(19) United States
(12) Patent Application Publication
(10) Pub. No.: US 2023/0309284 A1
(43) Pub. Date: Sep. 28, 2023

(54) DIELECTRIC, IMPACT RESISTANT, EMI TEXTILE SLEEVE AND METHOD OF CONSTRUCTION THEREOF

(71) Applicant: FEDERAL-MOGUL POWERTRAIN LLC, Northville, MI (US)

(72) Inventors: Alice Kaing, Margny-les-Compiegne (FR); Melanie Veronneau, Borest (FR); Amelie Simoens, Compiegne (FR); Mickael Pujos, Saint Etienne (FR); Julien Deltor, Arges (RO)

(21) Appl. No.: 18/126,172

(22) Filed: Mar. 24, 2023

Related U.S. Application Data
(60) Provisional application No. 63/323,882, filed on Mar. 25, 2022.

(51) Int. Cl. H05K 9/00; B32B 27/28; B32B 27/12; B32B 5/02; D03D 15/283; D03D 15/67; D03D 1/00; D03D 15/513; D06M 15/643

(52) U.S. Cl. CPC H05K 9/009; B32B 27/283; B32B 27/12; B32B 5/024; B32B 5/02; D03D 15/283; D03D 15/67; D03D 1/0058; D03D 15/513; D06M 15/643; D10B 2505/00; D10B 2401/02; B32B 2307/7265; B32B 2307/204; D10B 2401/16; B32B 2307/558; B32B 2307/306; D10B 2401/04; B32B 2262/02; D06M 2101/16

(57) ABSTRACT

A textile sleeve for routing and protecting an elongate member has a wrappable wall including a textile layer having an inner surface and an opposite outer surface extending lengthwise between opposite ends and widthwise between opposite edges. The opposite edges are configured to be wrapped about a central longitudinal axis to bound a central cavity extending lengthwise along the central longitudinal axis between the opposite ends. The textile layer is formed of yarns interlaced with one another, wherein a least some of the yarns include metal wire(s). A silicone-based layer is disposed about the outer surface of the textile layer to provide enhanced heat-resistance, dielectric protection and impact resistance.

### CROSS-REFERENCE TO RELATED APPLICATION

This application claims the benefit of U.S. Provisional Application Ser. No. 63/323,882, filed Mar. 25, 2022, which is incorporated herein by reference in its entirety.

### BACKGROUND OF THE INVENTION

### 1. Technical Field

This invention relates generally to textile sleeves for protecting elongate members, and more particularly to flexible, dielectric, impact resistant, electromagnetic interference resistant textile sleeves.

### 2. Related Art

It is known to contain and protect elongate members, such as wires and wire harnesses, for example, in textile sleeves to provide protection to cables, wires, and hoses contained therein. Improvements of known textile sleeves are desired to provide enhanced protection, including dielectric resistance protection, ease of grounding and coupling with adjacent textile sleeves, impact resistance protection, protection against electromagnetic interference, protection against contamination from solid debris and fluid, while also being flexible for routing cables, wires or hoses through winding areas, and while also having a low, non-bulky radially extending profile for applications having tight passages and weight restrictions, such as aircraft and aerospace applications, for example, all while being economical in manufacture.

### SUMMARY OF THE INVENTION

One aspect of the invention provides a textile sleeve for routing and protecting an elongate member. The textile sleeve has a wrappable wall including a textile layer having an inner surface and an opposite outer surface extending lengthwise between opposite ends and widthwise between opposite edges. The opposite edges are configured to be wrapped about a central longitudinal axis to bound a central cavity extending lengthwise along the central longitudinal axis between the opposite ends. The textile layer is formed of yarns interlaced with one another, wherein a least some of the yarns include metal wire(s). A silicone-based layer is disposed about the outer surface of the textile layer to provide enhanced heat-resistance, dielectric protection and impact resistance.

In accordance with another aspect of the invention, at least some of the yarns are formed of multifilaments resistant to heat and/or monofilaments resistant to heat.

In accordance with another aspect of the invention, at least some of the yarns are formed of polyester.

In accordance with another aspect of the invention, at least some of the multifilaments resistant to heat and/or monofilaments resistant to heat are provided as wires.

In accordance with another aspect of the invention, the entirety of the multifilaments resistant to heat and/or monofilaments resistant to heat can be provided as wires.

In accordance with another aspect of the invention, the yarns of the textile layer can be braided with one another.

In accordance with another aspect of the invention, the yarns of the textile layer can be woven with one another.

In accordance with another aspect of the invention, the yarns can include warp yarns extending generally parallel to the central longitudinal axis and weft yarns extending generally transversely to the central longitudinal axis, wherein the warp yarns are woven with the weft yarns.

In accordance with another aspect of the invention, at least some of the weft yarns can be heat-set to bias the wall to take-on a tubular configuration with the opposite edges being biased in overlapping relation with one another.

In accordance with another aspect of the invention, the silicone-based layer can be provided to penetrate through the textile layer, wherein the silicone-based layer extends radially inwardly from the inner surface of the textile layer to provide a soft, generally smooth innermost surface to inhibit abrading the elongate member disposed in the cavity.

In accordance with another aspect of the invention, the silicone-based layer can be bonded to the textile layer.

In accordance with another aspect of the invention, the silicone-based layer can be formed as a separate piece of material, and then afterward, disposed about the textile layer, wherein the silicone-based layer is readily separable from the textile layer.

In accordance with another aspect of the invention, the silicone-based layer can be formed being generally flush with one of the opposite edges of the textile layer and recessed from the other of the opposite edges of the textile layer.

In accordance with another aspect of the invention, the opposite edges of the textile layer can be configured to be wrapped into overlapping relation with one another to bring opposite edges of the silicone-based layer into abutting relation with one another.

In accordance with another aspect of the invention, the silicone-based layer can be formed as a separate piece of material and afterward disposed about the textile layer, wherein the silicone-based layer is readily separable from the textile layer.

In accordance with another aspect of the invention, a method of constructing a wrappable textile sleeve for routing and protecting an elongate member is provided. The method includes interlacing yarn to form a textile layer having an inner surface and an outer surface extending along a central longitudinal axis between opposite ends, wherein the inner surface is configured to bound a cavity sized for receipt of the elongate member, wherein at least some of the yarn includes metal wires. The method further includes disposing a silicone-based layer about the outer surface.

In accordance with another aspect of the invention, the method can further include interlacing the yarns with one another in a weaving process.

In accordance with another aspect of the invention, the method can further include weaving the yarns including warp yarns extending generally parallel to the central longitudinal axis and weft yarns extending generally transversely to the warp yarns, and providing at least some of the warp yarns and/or weft yarns as metal wires.

In accordance with another aspect of the invention, the method can further include providing all of the warp yarns and/or weft yarns as metal wires.

In accordance with another aspect of the invention, the method can further include molding the silicone-based outer layer about the outer surface of the textile layer.

In accordance with another aspect of the invention, the method can further include causing the silicone-based layer to extend radially inwardly from said inner surface of said textile layer.

### BRIEF DESCRIPTION OF THE DRAWINGS

These and other aspects, features and advantages will become readily apparent to those skilled in the art in view of the following detailed description of presently preferred embodiments and best mode, appended claims, and accompanying drawings, in which:

FIG. 1 is a schematic perspective view of a wrappable sleeve constructed in accordance with one aspect of the invention, with the wrappable sleeve shown wrapped about an elongate member to be protected therein;

FIG. 2A schematically illustrates a weaved section of a portion of an interlaced layer of the sleeves of FIGS. 1A and 1B;

FIG. 2B schematically illustrates a braided section of a portion of an interlaced layer of the sleeves of FIGS. 1A and 1B;

FIG. 3A is a perspective view illustrating a silicone-based outer layer and an underlying inner textile layer of a wrappable sleeve constructed in accordance with an aspect of the invention;

FIG. 3B is a perspective side view illustrating the wrappable sleeve of FIG. 3A showing a separate textile layer being joined to the inner textile layer of the wrappable sleeve in accordance with another aspect of the invention;

FIG. 3C is an end view illustrating the wrappable sleeve of FIG. 3A showing a ground member joined to the inner textile layer of the wrappable sleeve in accordance with another aspect of the invention;

FIG. 4A is a perspective view illustrating a wrappable sleeve constructed in accordance with another aspect of the invention, with a wall of the sleeve opened via an externally applied force to illustrate an inner textile layer of the wrappable sleeve; and

FIG. 4B is an end view of the wrappable sleeve of FIG. 4A.

### DETAILED DESCRIPTION OF PREFERRED EMBODIMENTS

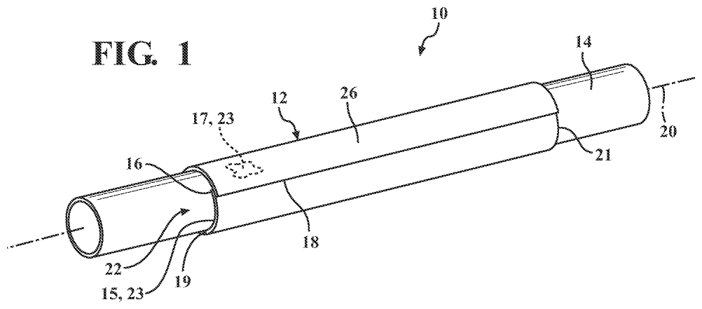

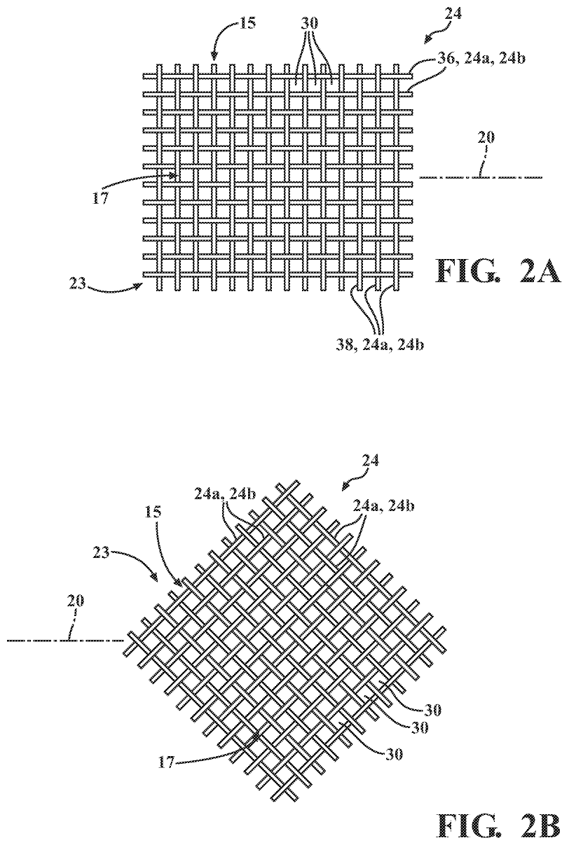

Referring in more detail to the drawings, FIG. 1 shows a schematic representation of a wrappable textile sleeve 10 constructed in accordance with an aspect of the invention. The sleeve 10 has a flexible, elongate wall 12 for routing and protecting at least one or more elongate member(s) 14, such as a cable, wires, and pipe, for example, to provide dielectric protection, protection against abrasion, protection against thermal conditions including high heat and fire, fluid absorption and ingress, e.g. water, oil, fuel, and the like, and other environmental conditions, such as contamination. The wall 12 can be constructed having any suitable size, including length and diameter. The wall 12 includes an inner, interlaced textile layer 23 having an inner surface 15 and an opposite outer surface 17 extending lengthwise about a longitudinal central axis 20 between opposite ends 19, 21, with inner surface 15 bounding a cavity 22 sized for receipt of the elongate member 14 therein. The wrappable sleeve 10 has opposite edges 16, 18 that extend parallel or generally parallel (intended to mean that to the naked eye, a person possessing ordinary skill in the art (POSA) would view the relationship to be parallel, though it may not be truly parallel) to the longitudinal central axis 20, wherein the opposite edges 16, 18 are wrappable into overlapping relation with one another in “cigarette wrapped” fashion to fully enclose the elongate member 14 within the central cavity 22. The inner, interlaced textile layer 23 is formed of yarns 24 interlaced with one another in one of a woven (a portion of the entire woven textile layer 23 is shown in FIG. 2A, with the remaining woven portion not shown being the same) or braided (a portion of the entire braided textile layer 23 is shown in FIG. 2B, with the remaining braided portion not shown being the same) fashion, wherein at least some of the yarns 24 include multifilaments 24a (a multifilament is a term well known to a POSA, known to be a single yarn including multiple filaments intertwined with one another) resistant to heat and/or monofilaments 24b (a monofilament is a term well known to a POSA, known to be a single, solid filament of material) resistant to heat. A silicone-based coating, also referred to as layer 26, is disposed about the outer surface 17 of the interlaced textile layer 23, shown as being disposed to cover the entirety of the outer surface 17, wherein the silicone-based layer 26 provides dielectric protection, while enhancing the heat-resistance and abrasion protection to the elongate member 14, and protection against fluid absorption/ingress.

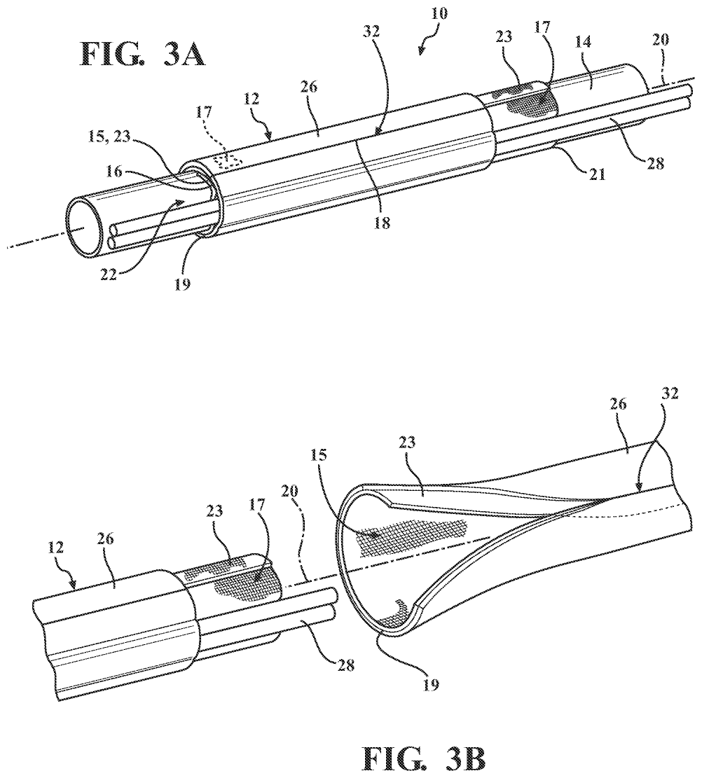

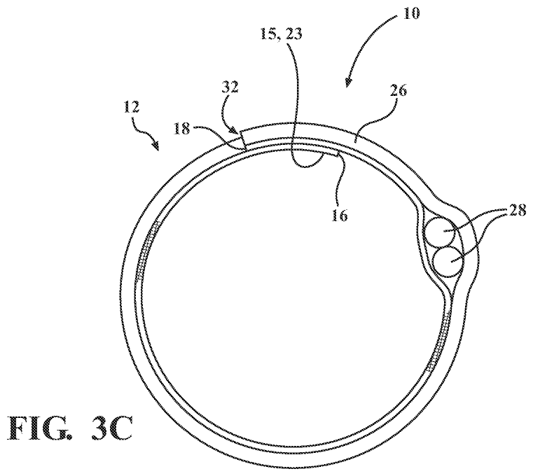

The silicone-based layer 26 is a fluid impervious coating, thereby being impervious to water, fuel (e.g. kerosene), oil, and the like, to render the wall 12 fluid impervious as well as fluid repellant. As such, fluid is prevented from being absorbed by the interlaced layer 23, thus, preventing water, fuel and the like from compromising the ability of the sleeve 10 to provide the desired levels of protection. The silicone-based layer 26 can be provided as a high density silicon to achieve increased mechanical, electrical and impact protection. Further yet, the silicone-based layer 26 can include at least one or both of a flame retardant and a heat stabilizer, and can be provided being flame resistant and self-extinguishing if exposed to flame. The silicone-based layer 26 can be provided having a thickness between about 0.1-3.0 mm, by way of example and without limitation, thereby contributing to the wall 12 having a radially narrow, low profile, thereby enhancing the flexibility and ability to be routed in relatively small, tight spaces. The silicone-based layer 26 can be formed as a separate piece of material, and then afterward, disposed about the textile layer, such that the silicone-based layer is readily separable from the textile layer. As such, as shown in FIG. 3B, the silicone-based layer 26 can be separate away from the textile layer 23, such as may be desired to join, also referred to as couple, a secondary textile layer 23a to the primary textile layer 23, and/or to attach a ground member 28, such as a braided or solid wire ground cable, by way of example and without limitation, to the textile layer 23. The ground member 28 can be easily disposed in overlying, abutting relation with the textile layer 23, whereupon the silicone-based layer 26 can be released to automatically wrap into overlying relation with the ground member 28 and the textile layer 23, thereby capturing and sandwiching the ground member 28 between the textile layer 23 and the silicone-based layer 26.

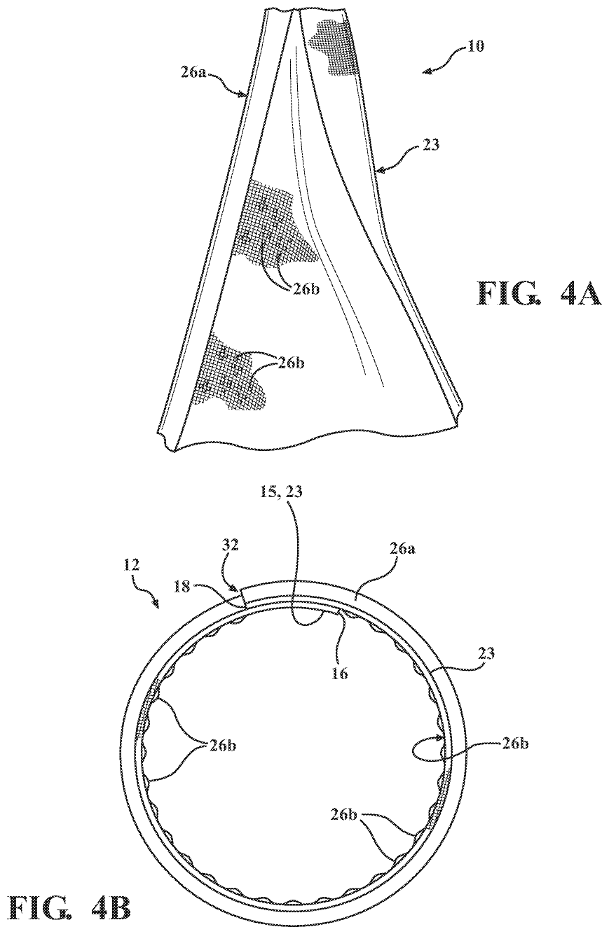

In accordance with another aspect of the disclosure, as shown in FIGS. 4A and 4B, the silicone-based layer 26a penetrates through interstices of the textile layer 23, wherein the silicone-based layer 26a can extend flush with or radially inwardly from the inner surface 15 of the textile layer 23, thereby providing a soft, generally smooth innermost surface 26b of the silicone-based layer material for abutment with an outer surface of the elongate member 14. As such, the outer surface of the elongate member 14 is protected against abrasion by being contacted by the soft, elastic material 26b of the silicone-based layer 26a. To facilitate penetration of the silicone-based layer 26a through interstices, also referred to as openings, of the textile layer 23, the silicone-based layer 26 can be molded directly to the outer surface 17 of the textile layer 23, whereupon liquid material of the silicone-based layer 26a can flow though the openings radially inwardly of the textile layer inner surface 15. To further facilitate penetration of the silicone-based layer 26a through openings of the textile layer 23, the textile layer 23 can be formed via a loose weave (FIG. 2A) or loose braid (FIG. 2B), thereby providing increased size openings 30 through the woven or braided textile layer 23. Various molding processes are contemplated, such as injection molding, by way of example and without limitation, wherein the innermost surface of the silicone-based layer 26a extended radially inwardly of the inner surface 15 of the textile layer 23 can be formed as a smooth surface, if desired. As such, it is contemplated that the textile layer 23 could be encapsulated by the silicone-based layer 26a. As shown best in FIG. 4B, the silicone-based layer 26a can be formed to be flush or generally flush with an outer one of the opposite edges 18, and recessed from an inner one of the opposite edges 16, thereby allowing an outer surface of the textile layer 23 to be brought into direct contact with an inner surface of the textile layer 23 upon the opposite edges 16, 18 being brought into overlapping relation with one another. As such, optimal electromagnetic interference (EMI) protection can be provided by having a circumferentially continuous continuity of the inner layer 23, with wires of the inner layer 23 be in electrical contact with one another. With the opposite edges 16, 18 overlapped with one another, opposite edges of the silicone-based layer 26a can be brought into abutting relation with one another, forming a butt-type joint 32, thereby providing circumferentially continuous protection to the elongate member(s) 14. Accordingly, the distance of the recess of the silicone-based layer 26a from the edge 16 is equal or substantially equal to the distance of the overlap of the opposite edges 16, 18. Of course, if desired, the opposite edges of the silicone-based layer 26a can be brought into overlapping relation with one another.

The interlaced yarns 24 can be woven, including warp yarns 36 extending generally parallel to the central longitudinal axis 20 and weft yarns 38 extending generally transversely to the central longitudinal axis 20. The warp yarns 36 can be woven with the weft yarns 38 in any desired weave pattern, including a pain weave, twill weave, satin weave or basket weave, for example, with the plain weave pattern being preferred to provide a smooth, stable and uniform protection pattern, with the smoothness facilitating bonding of the silicone-base coating 26 to the outer surface 17. The warp yarns 36 can be provided entirely from the multifilaments 24a, with the multifilaments 24a being resistant to heat (high temperature resistant); entirely from the monofilaments 24b, with the monofilaments 24b being resistant to heat (high temperature resistant), or a mixture thereof. In similar fashion, the weft yarns 38 can be provided entirely from the multifilaments 24a, with the multifilaments 24a being resistant to heat; entirely from the monofilaments 24b, with the monofilaments 24b being resistant to heat, or a mixture thereof. At least some of the warp yarns 36 and/or the weft yarns 38 are provided as wire, whether single filaments of wire (considered monofilaments), or bundled wires (considered multifilaments, wherein the bundled wires can be provided as mini braids, by way of example and without limitation). Otherwise, some of the warp yarns 36 and/or the weft yarns 38 can be formed of a polymeric material, including a heat-settable polymeric material, such that the heat-settable polymeric material can be heat-set to bias the opposite edges 16, 18 into overlapping relation with one another.

In accordance with another aspect of the disclosure, with reference to FIGS. 2A and 2B, the textile layer 23 can be woven (FIG. 2A) or braided (FIG. 2B) with the aforementioned multifilaments 24a and/or monofilaments 24b.

In accordance with another aspect of the invention, a method of constructing a textile sleeve 10 is provided. The method includes interlacing yarn 24 to form a textile layer 23 having an inner surface 15 and an outer surface 17 extending along a central longitudinal axis 20 between opposite ends 16, 18. Further, configuring the inner surface 15 to bound a cavity 22 sized for receipt of the elongate member 14, wherein at least some of the yarn 24 include metal wires. Further, disposing a silicone-based layer 26 about the outer surface 17.

In accordance with another aspect of the invention, the method can further include interlacing the yarns 24 with one another in a weaving process.

In accordance with another aspect of the invention, the method can further include weaving the yarns 24 including warp yarns 36 extending generally parallel to the central longitudinal axis 20 and weft yarns 38 extending generally transversely to the warp yarns 36, and providing at least some of the warp yarns 36 and/or weft yarns 38 as metal wires.

In accordance with another aspect of the invention, the method can further include providing all of the warp yarns 36 and/or weft yarns 38 as metal wires, such as having a diameter between about 0.05 to 0.15 mm, by way of example and without limitation.

In accordance with another aspect of the invention, the method can further include molding the silicone-based layer 26 about the outer surface 17 of the textile layer 23.

In accordance with another aspect of the invention, the method can further include causing the silicone-based layer 26 to extend radially inwardly from the inner surface 15 of the textile layer 23.

Obviously, many modifications and variations of the present invention are possible in light of the above teachings. It is contemplated that all features of all claims and of all embodiments can be combined with each other, so long as such combinations would not contradict one another. It is, therefore, to be understood that within the scope of the appended claims, the invention may be practiced otherwise than as specifically described.

What is claimed is:

1. A wrappable textile sleeve for routing and protecting an elongate member, comprising:
a textile layer having an inner surface and an opposite outer surface extending lengthwise between opposite ends and widthwise between opposite edges, said opposite edges being configured to be wrapped about a central longitudinal axis to bound a central cavity extending lengthwise along the central longitudinal axis between said opposite ends, said textile layer being formed of yarns interlaced with one another, wherein a least some of said yarns include metal wires; and
a silicone-based layer disposed about said outer surface.

2. The wrappable textile sleeve of claim 1, wherein at least some of said yarns are formed of multifilaments resistant to heat and/or monofilaments resistant to heat.

3. The wrappable textile sleeve of claim 2, wherein at least some of said yarns are formed of a polymeric material and/or a heat-settable polymeric material.

4. The wrappable textile sleeve of claim 2, wherein at least some of said multifilaments resistant to heat and/or monofilaments resistant to heat are provided as wires.

5. The wrappable textile sleeve of claim 4, wherein the entirety of said multifilaments resistant to heat and/or monofilaments resistant to heat are provided as wires.

6. The wrappable textile sleeve of claim 1, wherein said yarns of said textile layer are braided.

7. The wrappable textile sleeve of claim 1, wherein said yarns of said textile layer are woven.

8. The wrappable textile sleeve of claim 7, wherein said yarns include warp yarns extending generally parallel to said central longitudinal axis and weft yarns extending generally transversely to said central longitudinal axis, said warp yarns being woven with said weft yarns.

9. The wrappable textile sleeve of claim 8, wherein at least some of said weft yarns are heat-set to bias said wall to take-on a tubular configuration with said opposite edges being biased in overlapping relation with one another.

10. The wrappable textile sleeve of claim 1, wherein said silicone-based layer penetrates through said textile layer, wherein said silicone-based layer extends radially inwardly from said inner surface of said textile layer.

11. The wrappable textile sleeve of claim 10, wherein said silicone-based layer is bonded to said textile layer.

12. The wrappable textile sleeve of claim 11, wherein said silicone-based layer is generally flush with one of said opposite edges and recessed from the other of said opposite edges.

13. The wrappable textile sleeve of claim 12, wherein said opposite edges are configured to be wrapped into overlapping relation with one another to bring opposite edges of said silicone-based layer into abutting relation with one another.

14. The wrappable textile sleeve of claim 1, wherein said silicone-based layer is formed as a separate piece of material and afterward disposed about said textile layer, wherein said silicone-based layer is readily separable from said textile layer.

15. A method of constructing a wrappable textile sleeve for routing and protecting an elongate member, comprising:
interlacing yarn to form a textile layer having an inner surface and an outer surface extending along a central longitudinal axis between opposite ends, said inner surface being configured to bound a cavity sized for receipt of the elongate member, wherein at least some of said yarn includes metal wires; and
disposing a silicone-based layer about the outer surface.

16. The method of claim 15, further including interlacing the yarns with one another in a weaving process.

17. The method of claim 16, further including weaving the yarns including warp yarns extending generally parallel to the central longitudinal axis and weft yarns extending generally transversely to the warp yarns, and providing at least some of the warp yarns and/or weft yarns as metal wires.

18. The method of claim 17, further including providing all of the warp yarns and/or weft yarns as metal wires.

19. The method of claim 16, further including molding the silicone-based outer layer about the outer surface of the textile layer.

20. The method of claim 19, further including causing the silicone-based layer to extend radially inwardly from said inner surface of said textile layer.
